(19) United States
(12) Patent Application Publication
(10) Pub. No.: US 2023/0335455 A1
(43) Pub. Date: Oct. 19, 2023

(54) SEMICONDUCTOR DEVICE, POWER CONVERSION DEVICE, AND MOBILE BODY

(71) Applicant: Mitsubishi Electric Corporation, Tokyo (JP)

(72) Inventor: Yuta FUKUSHIMA, Fukuoka (JP)

(73) Assignee: Mitsubishi Electric Corporation, Tokyo (JP)

(21) Appl. No.: 18/044,637

(22) PCT Filed: Dec. 16, 2020
(86) PCT No.: PCT/JP2020/046879

§ 371 Date: Mar. 9, 2023

(51) Int. Cl. H01L 23/367

(52) U.S. Cl. CPC H01L 23/3675; H01L 23/49811

(57) ABSTRACT

To provide a semiconductor device with improved reliability by suppressing a degree at which heat generated by a semiconductor element is transferred through a heat radiation plate to a bonding portion between a metal electrode and an insulating substrate. The semiconductor device includes a heat radiation plate, at least one insulating substrate, a semiconductor element, and a metal electrode. The at least one insulating substrate is bonded on one main surface of the heat radiation plate, the semiconductor element is bonded on the one main surface via any of the at least one insulating substrate, the metal electrode is bonded on the one main surface via any of the at least one insulating substrate. The heat radiation plate has, in a region between a region where the semiconductor element is bonded and a region where the metal electrode is bonded, a narrowed portion.

### TECHNICAL FIELD

The present disclosure relates to a semiconductor device, a power conversion device, and a mobile body.

### BACKGROUND ART

Patent Document 1 discloses, for example, a semiconductor device in which each of a semiconductor element and an electrode are bonded to a heat radiation plate via an insulating member.

### PRIOR ART DOCUMENT

### Patent Document

Patent Document 1: Japanese Patent Application Laid-Open No. 2005-276968

### SUMMARY

### Problem to be Solved by the Invention

In a semiconductor device, when each of a semiconductor element and a metal electrode are bonded to a heat radiation plate via an insulating substrate, heat generated by the semiconductor element is transferred to a bonding portion between the metal electrode and the insulating substrate through the heat radiation plate. If heat generated by the semiconductor element is easily transferred to the bonding portion between the metal electrode and the insulating substrate, the bonding portion between the metal electrode and the insulating substrate is likely to deteriorate, thereby reducing reliability of the semiconductor device.

The present disclosure is intended to solve such a problem, and an object thereof is to provide a semiconductor device in which a degree at which heat generated by a semiconductor element is transferred to a bonding portion between a metal electrode and an insulating substrate through a heat radiation plate is suppressed and reliability is improved, a power conversion device using the semiconductor device, and a mobile body using the power conversion device.

### Means to Solve the Problem

A semiconductor device of the present disclosure includes a heat radiation plate, at least one insulating substrate, a semiconductor element, and a metal electrode, in which the at least one insulating substrate is bonded on one main surface of the heat radiation plate, the semiconductor element is bonded on the one main surface of the heat radiation plate via any of the at least one insulating substrate, the metal electrode is bonded on the one main surface of the heat radiation plate via any of the at least one insulating substrate, and the heat radiation plate has, in a region between a region where the semiconductor element is bonded and a region where the metal electrode is bonded, a narrowed portion having a narrower width in a thickness direction than widths of other locations.

A power conversion device of the present disclosure includes a main conversion circuit that has the semiconductor device of the present disclosure, and which converts input electric power and outputs converted electric power, and a control circuit that outputs, to the main conversion circuit, a control signal controlling the main conversion circuit.

A mobile body of the present disclosure includes the power conversion device of the present disclosure and an electric motor driven by the electric power output by the power conversion device.

### Effects of the Invention

The heat radiation plate of the semiconductor device of the present disclosure has, in a region between a region where the semiconductor element is bonded and a region where the metal electrode is bonded, a narrowed portion having a narrower width in a thickness direction than that of other locations. Thus, the semiconductor device of the present disclosure is one in which a degree at which heat generated by the semiconductor element is transferred to the bonding portion between the metal electrode and the insulating substrate through the heat radiation plate is suppressed, and reliability is improved.

The power conversion device of the present disclosure includes the main conversion circuit that includes the semiconductor device of the present disclosure, and which converts input electric power and outputs the converted electric power. Thus, the power conversion device including the semiconductor device of the present disclosure is provided.

The mobile body of the present disclosure includes the power conversion device of the present disclosure. Thus, the mobile body using the power conversion device is provided.

In addition, objects, characteristics, aspects, and advantages related to the techniques disclosed in the present specification will become more apparent from the detailed description and accompanying drawings shown below.

### BRIEF DESCRIPTION OF DRAWINGS

FIG. 1 is a diagram showing a configuration of a semiconductor device according to a first embodiment.

FIG. 2 is a diagram showing a configuration of a semiconductor device according to a second embodiment.

FIG. 3 is a diagram showing a configuration of a heat radiation plate of a semiconductor device according to a third embodiment.

FIG. 4 is a diagram showing a configuration of the semiconductor device according to the third embodiment.

FIG. 5 is a diagram showing a configuration of a semiconductor device according to a fourth embodiment.

FIG. 6 is a diagram showing a configuration of a semiconductor device according to a fifth embodiment.

FIG. 7 is a diagram showing a configuration of a semiconductor device according to a sixth embodiment.

FIG. 8 is a diagram showing a configuration of a semiconductor device according to a seventh embodiment.

FIG. 9 is a diagram showing a configuration of a semiconductor device according to an eighth embodiment.

FIG. 10 is a diagram showing a configuration of a semiconductor device according to the eighth embodiment.

FIG. 11 is a diagram showing a configuration of a power conversion system to which a power conversion device according to a tenth embodiment is applied.

FIG. 12 is a diagram showing a configuration of a mobile body according to an eleventh embodiment.

FIG. 13 is a diagram showing a configuration of a semiconductor device of a comparative example.

### DESCRIPTION OF EMBODIMENTS

### Comparative Example

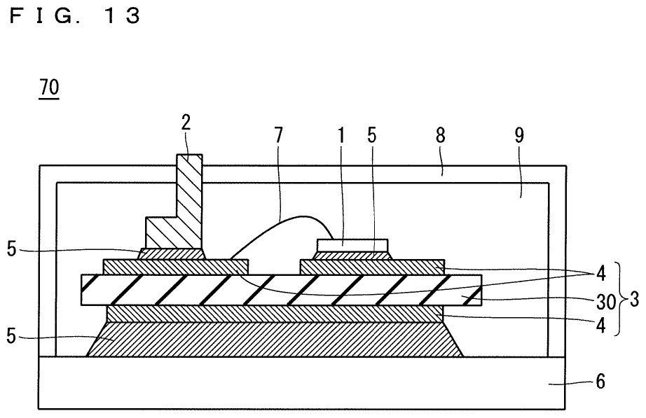

FIG. 13 shows a semiconductor device 70 as a comparative example of each later-described embodiment.

The semiconductor device 70 includes a semiconductor element 1, a metal electrode 2, an insulating substrate 3, a bonding material 5, a heat radiation plate 6, a wire 7, a case housing 8, and a sealing material 9.

The insulating substrate 3 includes an insulating layer 30 and metal patterns 4. A material of the insulating layer 30 is, for example, ceramic. The metal patterns 4 are formed on both main surfaces of the insulating layer 30. A material of the metal patterns 4 is, for example, copper.

The semiconductor element 1 is, for example, an insulated gate bipolar transistor (IGBT), a metal oxide semiconductor field effect transistor (MOSFET), or a free wheeling diode (FWD). The semiconductor element 1 is, for example, a silicon semiconductor element using a silicon semiconductor.

The insulating substrate 3 is bonded to the heat radiation plate 6 via the bonding material 5. The bonding material 5 is, for example, solder. A material of the heat radiation plate 6 is, for example, copper, aluminum, or both.

The semiconductor element 1 and the metal electrode 2 are bonded to the metal patterns 4 on a surface of the insulating substrate 3 via the bonding material 5. That is, the semiconductor element 1 and the metal electrode 2 are bonded on one main surface of the heat radiation plate 6 via the insulating substrate 3. The semiconductor element 1 and the metal electrode 2 are electrically connected via the metal patterns 4 and the wire 7.

The semiconductor element 1, the insulating substrate 3, and the wire 7 are disposed in the case housing 8 and protected by the sealing material 9. A material of the case housing 8 is, for example, polyphenylene sulfide (PPS) resin. The sealing material 9 is, for example, silicone gel. The metal electrode 2 is used to electrically connect the semiconductor device 70 to an external circuit.

When the semiconductor element 1 operates, heat is generated. Heat generated by the semiconductor element 1 is transferred through the heat radiation plate 6 to a bonding portion by the bonding material 5 between the metal electrode 2 and the insulating substrate 3. As a result, thermal stress is generated at the bonding portion by the bonding material 5 between the metal electrode 2 and the insulating substrate 3, the bonding material 5 becomes brittle, and the metal electrode 2 becomes more likely to peel off from the insulating substrate 3. In this way, heat transferred from the semiconductor element 1 to the bonding portion by the bonding material 5 between the metal electrode 2 and the insulating substrate 3 is a factor in shortening the service life of the semiconductor device 70.

### A. First Embodiment

<A-1. Configuration>

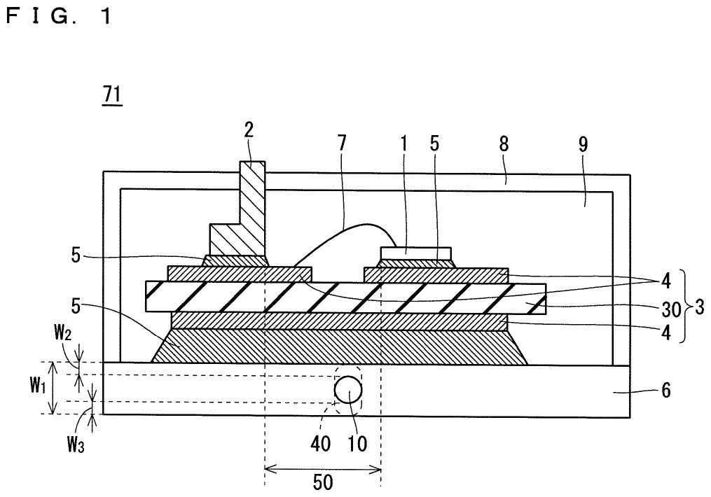

FIG. 1 shows a semiconductor device 71 of the present embodiment.

When compared to the semiconductor device 70, the semiconductor device 71 differs in that a hole 10 is provided in the heat radiation plate 6. The semiconductor device 71 is similar to the semiconductor device 70 in other respects.

In the semiconductor device 71, the hole 10 is provided in a region of the heat radiation plate 6 between a region where the semiconductor element 1 is bonded and a region where the metal electrode 2 is bonded, that is, a region 50 shown in FIG. 1. The hole 10 is, for example, a through hole that passes through from one side surface of the heat radiation plate 6 to another side surface opposite to the one side surface. In addition, the hole 10 is, for example, a blind hole that has an opening on only one side surface of the heat radiation plate 6 and that does not pass through to another side surface.

The hole 10 has a columnar shape and extends in a direction that intersects with a direction connecting a region where the semiconductor element 1 is bonded and a region where the metal electrode 2 is bonded (for example, a perpendicular direction of the paper surface of FIG. 1).

In this way, the heat radiation plate 6 has, in the region between the region where the semiconductor element 1 is bonded and the region where the metal electrode 2 is bonded, a narrowed portion 40 having a narrower width in the thickness direction than that of other locations due to the hole 10. Here, the expression that the width of the narrowed portion 40 in the thickness direction is narrower than that of other locations means that the width of the narrowed portion 40 in the thickness direction excluding the hole 10, that is, W₂+W₃, is smaller than a width W₁ of the heat radiation plate 6 in the thickness direction in other locations.

<A-2. Operation>

When the semiconductor element 1 operates, heat is generated. While heat generated from the semiconductor element 1 is transferred through the heat radiation plate 6 to the bonding portion by the bonding material 5 between the metal electrode 2 and the insulating substrate 3, a degree at which heat generated from the semiconductor element 1 is transferred through the heat radiation plate 6 to the bonding portion by the bonding material 5 between the metal electrode 2 and the insulating substrate 3 is suppressed due to the heat radiation plate 6 having the narrowed portion 40. As a result, thermal stress generated at the bonding portion by the bonding material 5 between the metal electrode 2 and the insulating substrate 3 during operation of the semiconductor device 71 is suppressed, and reliability of the semiconductor device 71 is improved.

In general, the thermal conductivity of air is about 0.0241 W/mK at around room temperature, and this is smaller than the thermal conductivity of copper, at about 403 W/mK, and the thermal conductivity of aluminum, at about 236 W/mK, which are both examples of the material of the heat radiation plate 6. Accordingly, by filling the hole 10 with air, the degree at which heat generated from the semiconductor element 1 is transferred through the heat radiation plate 6 to the bonding portion by the bonding material 5 between the metal electrode 2 and the insulating substrate 3 is suppressed. However, the inside of the hole 10 is not necessarily filled with air. The semiconductor device 71 may, for example, contain inside the hole 10 a substance having a smaller thermal conductivity than that of the material of the heat radiation plate 6, such as resin.

### B. Second Embodiment

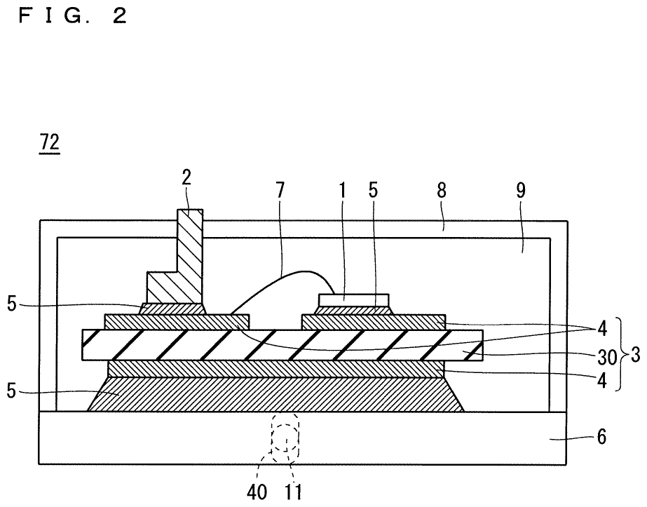

FIG. 2 shows a semiconductor device 72 of the present embodiment.

When compared with the semiconductor device 71, the semiconductor device 72 differs in that an internal cavity 11 having no opening is provided instead of the hole 10 between the region of the heat radiation plate 6 where the semiconductor element 1 is bonded and the region of the heat radiation plate 6 where the metal electrode 2 is bonded. The semiconductor device 72 is similar to the semiconductor device 71 in other respects.

The internal cavity 11 has a columnar shape and extends in a direction that intersects with a direction connecting a region where the semiconductor element 1 is bonded and a region where the metal electrode 2 is bonded.

The heat radiation plate 6 of the semiconductor device 72 has, in the region between the region where the semiconductor element 1 is bonded and the region where the metal electrode 2 is bonded, a narrowed portion 40 having a narrower width in the thickness direction than that of other locations due to the internal cavity 11.

In the semiconductor device 72, the degree of transfer of heat generated from the semiconductor element 1 through the heat radiation plate 6 to the bonding portion by the bonding material 5 between the metal electrode 2 and the insulating substrate 3 is suppressed due to the narrowed portion 40. As a result, reliability of the semiconductor device 72 is improved.

The internal cavity 11 is formed, for example, by forming a blind hole then covering an opening portion of the blind hole with the same material as that of the heat radiation plate. Since the internal cavity 11 provided in the heat radiation plate 6 has no opening, the appearance of the heat radiation plate 6 can be made unchanged from that of the heat radiation plate 6 without the internal cavity 11.

The internal cavity 11 is filled with air. In the semiconductor device 72, infiltration of foreign matter such as thermal conductive grease applied between a heat sink and the heat radiation plate, moisture, or the like into the internal cavity 11 is prevented, and deterioration of heat insulation performance due to infiltration of foreign matter into the internal cavity 11 is prevented. However, the semiconductor device 72 may, for example, contain inside the internal cavity 11 a substance with a smaller thermal conductivity than that of the material of the heat radiation plate 6, such as resin.

### C. Third Embodiment

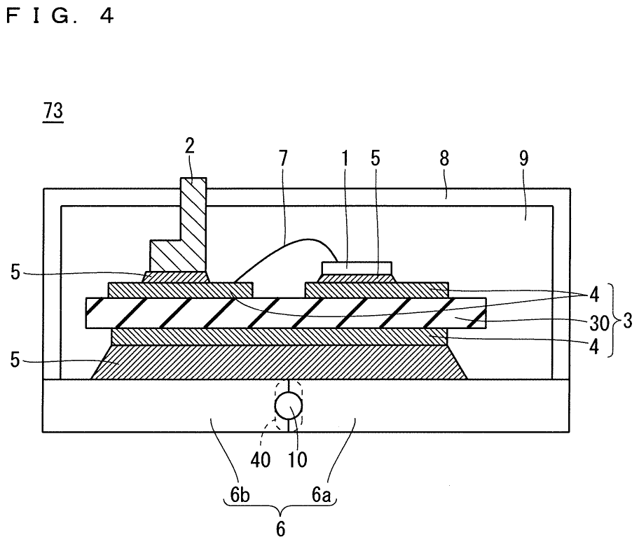

FIG. 4 shows a semiconductor device 73 of the present embodiment.

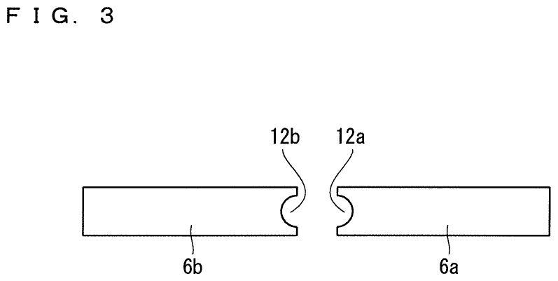

In the semiconductor device 73, the heat radiation plate 6 is formed by combining a plurality of independent portions, that is, a portion 6a and a portion 6b. As shown in FIG. 3, a depression portion 12a is provided on a side surface of the portion 6a, and a depression portion 12b is provided on a side surface of the portion 6b. In addition, as shown in FIG. 4, the hole 10 is formed by bringing together the depression portion 12a and the depression portion 12b. The semiconductor device 73 is similar to the semiconductor device 71 of the first embodiment in other respects.

In the semiconductor device 73, the heat radiation plate 6 has, in the region between the region where the semiconductor element 1 is bonded and the region where the metal electrode 2 is bonded, a narrowed portion 40 having a narrower width in the thickness direction than that of other locations due to the hole 10. In the semiconductor device 73, the degree of transfer of heat generated from the semiconductor element 1 through the heat radiation plate 6 to the bonding portion by the bonding material 5 between the metal electrode 2 and the insulating substrate 3 is suppressed due to the narrowed portion 40. As a result, reliability of the semiconductor device 73 is improved.

Instead of the hole 10, the internal cavity 11 described in the second embodiment may be formed by the depression portion on the side surface of the portion 6a and the depression portion on the side surface of the portion 6b.

In the present embodiment, since the heat radiation plate 6 is formed by combining the plurality of independent portions and the hole 10 is formed by bringing together the depression portion 12a of the portion 6a and the depression portion 12b of the portion 6b, the processing for forming the hole 10 is easy.

In the case of the structure disclosed in Patent Document 1, in which heat-resistant resin is provided between heat radiation portions, a number of components is increased, and further, since different materials require bonding, more processing is required. In the present embodiment, heat-resistant resin is not required between the portion 6a and the portion 6b. In addition, since the portion 6a and the portion 6b are made of the same material, the portion 6a and the portion 6b are easily bonded together.

The portion 6a and the portion 6b are bonded by, for example, a bonding material. In addition, the portion 6a and the portion 6b may be disposed such that they are in mutual contact without being bonded together.

### D. Fourth Embodiment

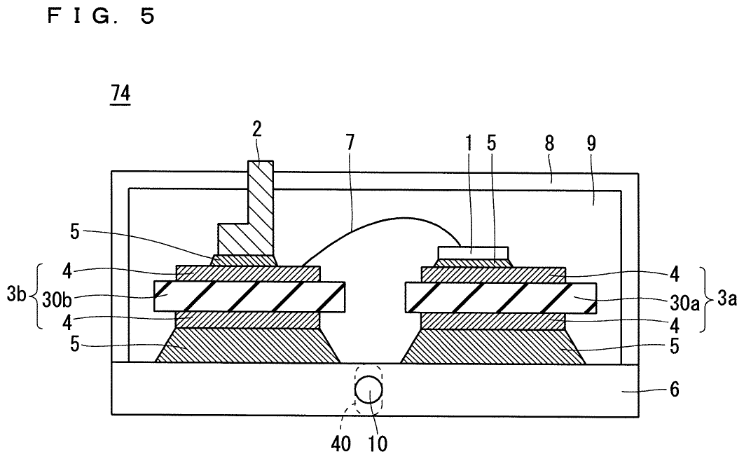

FIG. 5 shows a semiconductor device 74 of the present embodiment.

When compared with the semiconductor device 71 of the first embodiment, the semiconductor device 74 differs in that the semiconductor element 1 and the metal electrode 2 are bonded to different insulating substrates. The semiconductor device 74 is similar to the semiconductor device 71 in other respects.

The semiconductor device 74 may have a configuration in which a modification is added to the semiconductor device of the second or third embodiment such that the semiconductor element 1 and the metal electrode 2 are bonded to different insulating substrates.

As shown in FIG. 5, the semiconductor device 74 includes a plurality of insulating substrates, that is, an insulating substrate 3a and an insulating substrate 3b. The insulating substrate 3a includes an insulating layer 30a and the metal patterns 4. The metal patterns 4 are formed on both main surfaces of the insulating layer 30a. The insulating substrate 3b includes an insulating layer 30b and the metal patterns 4. The metal patterns 4 are formed on both main surfaces of the insulating layer 30b. The insulating substrate 3a and the insulating substrate 3b are bonded to the heat radiation plate 6 via the bonding material 5. The semiconductor element 1 is bonded to the insulating substrate 3a via the bonding material 5, and the metal electrode 2 is bonded to the insulating substrate 3b via the bonding material 5. That is, the semiconductor element 1 is bonded to the heat radiation plate 6 via the insulating substrate 3a, and the metal electrode 2 is bonded to the heat radiation plate 6 via the insulating substrate 3b.

In the semiconductor device 74, the degree of transfer of heat generated from the semiconductor element 1 through the heat radiation plate 6 to the bonding portion by the bonding material 5 between the metal electrode 2 and the insulating substrate 3b is also suppressed due to the narrowed portion 40. As a result, reliability of the semiconductor device 74 is improved.

In the semiconductor device 71 of the first embodiment, heat generated by the semiconductor element 1 is transferred to the metal electrode 2 through the insulating substrate 3. In the semiconductor device 74, since the semiconductor element 1 and the metal electrode 2 are bonded to different insulating substrates and have the sealing material 9 between the insulating substrate 3a and the insulating substrate 3b, heat generated by the semiconductor element 1 is difficult to be transferred to the bonding portion by the bonding material 5 between the metal electrode 2 and the insulating substrate 3.

### E. Fifth Embodiment

A modification may be added to the semiconductor devices of the first, third, and fourth embodiments such that a plurality of holes 10 is provided in the heat radiation plate 6, and a modification may be added to the semiconductor device of the second embodiment such that a plurality of internal cavities 11 is provided. In addition, the heat radiation plate 6 may be provided with at least two selected from the group of the through hole, the blind hole, and the internal cavity, or all of the through hole, the blind hole, and the internal cavity.

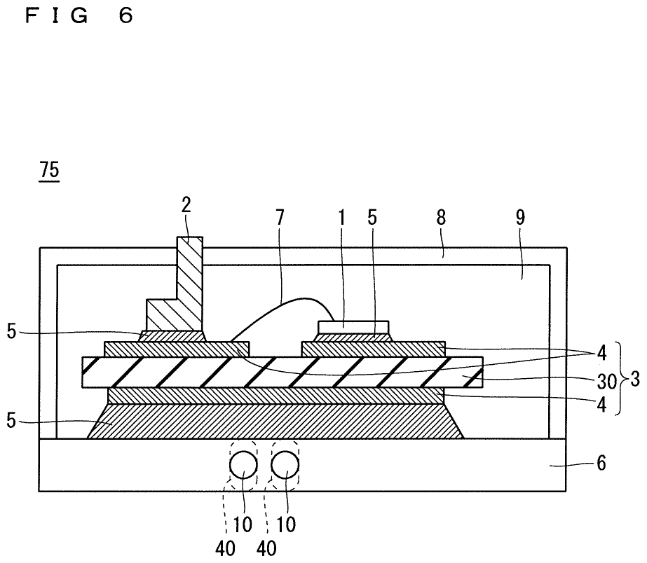

FIG. 6 shows a semiconductor device 75 of the present embodiment. In FIG. 6, the semiconductor device 75 is shown as a configuration in which, in contrast to the semiconductor device 71 of the first embodiment, the hole 10 has been changed to a plurality. The semiconductor device 75 is similar to the semiconductor device 71 in other respects.

In the semiconductor device 75, the plurality of holes 10 is arranged in a direction connecting the region where the semiconductor element 1 is bonded and the region where the metal electrode 2 is bonded. Each of the holes 10 extends in the direction intersecting with the direction connecting the region where the semiconductor element 1 is bonded and the region where the metal electrode 2 is bonded.

When a distance between the semiconductor element 1 and the metal electrode 2 is equal to or greater than a thickness of the heat radiation plate 6, by providing the plurality of holes 10, that is, by providing a plurality of narrowed portions 40, heat transferred from the semiconductor element 1 to the bonding portion by the bonding material 5 between the metal electrode 2 and the insulating substrate 3 can be further reduced when compared with a case in which one hole 10 is provided. As a result, reliability of the semiconductor device 75 is improved.

When a distance between the semiconductor element 1 and the metal electrode 2 is equal to or greater than the thickness of the heat radiation plate 6, while heat transferred from the semiconductor element 1 to the bonding portion by the bonding material 5 between the metal electrode 2 and the insulating substrate 3 can be reduced by widening the one hole 10 provided in the semiconductor device 71 of the first embodiment in the direction connecting the semiconductor element 1 and the metal electrode 2, by providing the plurality of holes 10, it is possible to suppress a reduction in strength of the heat radiation plate 6, and further, it is possible to allow less heat to be transferred from the semiconductor element 1 to the bonding portion by the bonding material 5 between the metal electrode 2 and the insulating substrate 3.

### F. Sixth Embodiment

In the first to fifth embodiments, the hole 10 or the internal cavity 11 is not limited to a columnar shape and may have a quadrangular prism shape, triangular prism shape, or another arbitrary shape as long as the narrowed portion 40 is formed in the region between the region where the semiconductor element 1 is bonded and the region where the metal electrode 2 is bonded. The shape of the hole 10 or the internal cavity 11 may be a shape that is easy to process in accordance with a shape and material of the heat radiation plate 6.

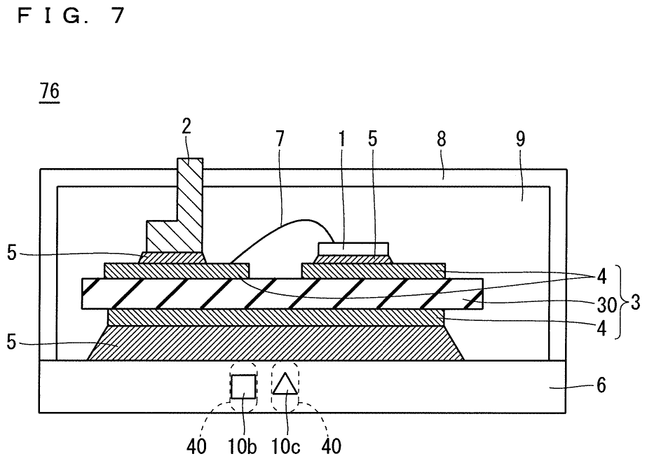

As an example of the semiconductor device 76 according to the present embodiment, FIG. 7 shows a configuration in which, in comparison to the semiconductor device 71 according to the first embodiment, a hole 10b having a quadrangular prism shape and a hole 10c having a triangular prism shape are provided in the heat radiation plate 6 instead of the hole 10 having a columnar shape. The semiconductor device 76 is similar to the semiconductor device 71 in other respects.

### G. Seventh Embodiment

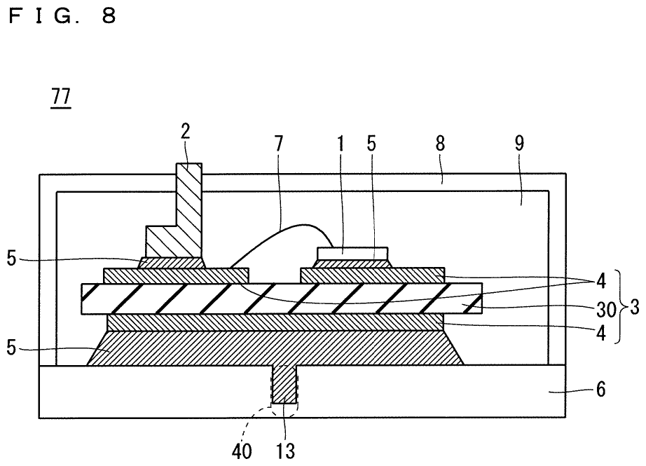

FIG. 8 is a diagram showing a semiconductor device 77 of the present embodiment.

In the semiconductor device 77, a depression portion 13 is provided on the main surface of the heat radiation plate 6 on a side where the semiconductor element 1 and the metal electrode 2 are bonded. The heat radiation plate 6 has the narrowed portion 40 in the region between the region where the semiconductor element 1 is bonded and the region where the metal electrode 2 is bonded. A width of the narrowed portion 40 in the thickness direction is narrower than that of other locations due to the depression portion 13.

A configuration of the semiconductor device 77 is similar to that of the semiconductor device 71 of the first embodiment except that the shape of the heat radiation plate 6 is different and the bonding material 5 is included in the depression portion 13.

The depression portion 13 extends in the direction that intersects with the direction connecting the region where the semiconductor element 1 is bonded and the region where the metal electrode 2 is bonded.

The semiconductor element 1 and the metal electrode 2 are bonded on the one main surface of the heat radiation plate 6 via the insulating substrate 3. That is, the semiconductor element 1 and the metal electrode 2 are bonded on the one main surface of the heat radiation plate 6 via the same insulating substrate. The insulating substrate 3 is bonded to the heat radiation plate 6 by the bonding material 5 at a position facing to the depression portion 13. Therefore, when the heat radiation plate 6 and the insulating substrate 3 are bonded together by the bonding material 5, the inside of the depression portion 13 is filled with the bonding material 5. That is, the semiconductor device 77 contains the bonding material 5 inside the depression portion 13. The bonding material 5 is, for example, solder.

Solder, which is an example of the bonding material 5, has a smaller thermal conductivity than copper or aluminum, which are materials of the heat radiation plate 6. For example, the thermal conductivity of a solder with a 50 Sn composition is 49 W/mK. Therefore, a degree at which heat generated from the semiconductor element 1 is transferred through the heat radiation plate 6 to the bonding portion by the bonding material 5 between the metal electrode 2 and the insulating substrate 3 is suppressed due to the configuration in which the depression portion 13 is provided in the heat radiation plate 6 and the solder is contained inside the depression portion 13. As a result, reliability of the semiconductor device 77 is improved.

In addition, the present embodiment may be combined with the fourth embodiment to replace the heat radiation plate 6 of the semiconductor device 74 of the fourth embodiment with the heat radiation plate 6 of the semiconductor device 77. In this case, for example, there is no insulating substrate 3a and insulating substrate 3b at a position facing to the depression portion 13, and the depression portion 13 is filled with the sealing material 9. While the sealing material 9 is, for example, silicone gel, silicone gel has a smaller thermal conductivity than that of copper or aluminum, which are materials of the heat radiation plate 6. Therefore, in such a configuration, the degree at which heat generated from the semiconductor element 1 is transferred through the heat radiation plate 6 to the bonding portion by the bonding material 5 between the metal electrode 2 and the insulating substrate 3 through the heat radiation plate 6 is also suppressed. As a result, reliability of the semiconductor device 77 is improved.

In the semiconductor device 77, since the depression portion 13 is provided on the main surface of the heat radiation plate 6, processing is easier and the cost can be suppressed when compared with, for example, the case of the first embodiment, in which the hole 10 having an opening on the side surface of the heat radiation plate 6 is provided in the heat radiation plate 6.

### H. Eighth Embodiment

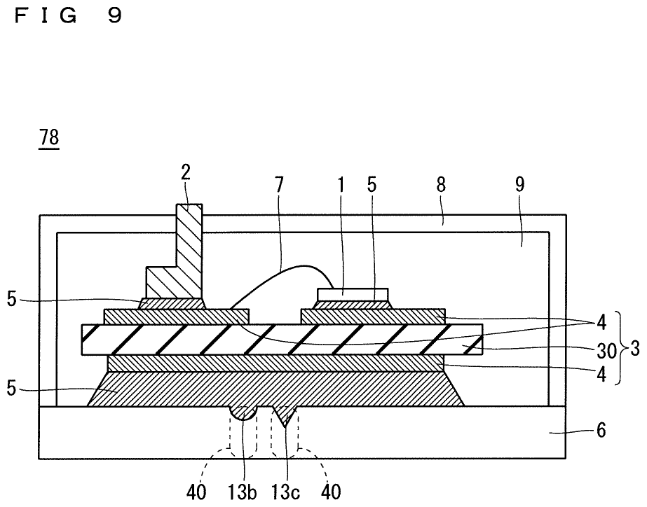

The shape of the depression portion provided in the heat radiation plate 6 is not limited as long as the narrowed portion 40 is formed in the region between the region where the semiconductor element 1 is bonded and the region where the metal electrode 2 is bonded, and the shape may be easy to process in accordance with a shape and material of the heat radiation plate 6. The depression portion does not need to be a depression portion having a rectangular cross section like the semiconductor device 77 of the seventh embodiment, and may be a depression portion having a V-shaped cross section or a depression portion having a semicircular cross section. In addition, a plurality of depression portions may be provided. As a semiconductor device 78 of the present embodiment, FIG. 9 shows a semiconductor device in which a depression portion 13b having a V-shaped cross section and a depression portion 13c having a semicircular cross section are provided in the heat radiation plate 6. The depression portion 13b and the depression portion 13c extend in the direction that intersects with the direction connecting the region where the semiconductor element 1 is bonded and the region where the metal electrode 2 is bonded.

In addition, the depression portions provided in the heat radiation plate 6 do not necessarily need to extend in the direction that intersects with the direction connecting the region where the semiconductor element 1 is bonded and the region where the metal electrode 2 is bonded. For example, the plurality of depression portions may be discretely arranged and disposed in the direction that intersects with the direction connecting the region where the semiconductor element 1 is bonded and the region where the metal electrode 2 is bonded.

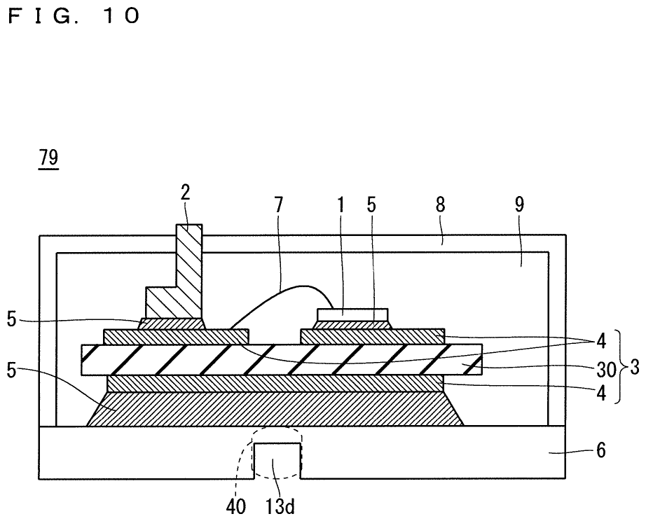

In a semiconductor device 79 shown in FIG. 10, a depression portion 13d is provided on the main surface of the heat radiation plate 6 on the side opposite to the side where the semiconductor element 1 and the metal electrode 2 are bonded via the insulating substrate 3, and this kind of depression portion 13d forms the narrowed portion 40 in the region between the region where the semiconductor element 1 is bonded and the region where the metal electrode 2 is bonded. The depression portion 13d extends in the direction that intersects with the direction connecting the region where the semiconductor element 1 is bonded and the region where the metal electrode 2 is bonded.

When the depression portion is provided on the main surface of the heat radiation plate 6 on the side opposite to the side where the semiconductor element 1 and the metal electrode 2 are bonded via the insulating substrate 3, the shape of the depression portion provided in the heat radiation plate 6 may be arbitrary, or a plurality of depression portions may be provided in the heat radiation plate 6.

### I. Ninth Embodiment

In the semiconductor device according to any one of the first to eighth embodiments, the semiconductor element 1 has been described as being, for example, a silicon semiconductor element, however, in the semiconductor device according to any one of the first to eighth embodiments, the semiconductor element 1 may be a wide band gap semiconductor element that uses a wide band gap semiconductor. That is, the semiconductor element 1 may include a wide band gap semiconductor.

The wide band gap semiconductor is a semiconductor having a larger band gap than that of silicon. Examples of the wide band gap semiconductor included in the semiconductor element 1 include, for example, silicon carbide, a gallium nitride-based material, or diamond.

The wide gap semiconductor element can operate at a higher temperature than the silicon semiconductor element. When the wide band gap semiconductor element capable of operating at a higher temperature is used as the semiconductor element 1 instead of the silicon semiconductor element, for example, a cooling system for cooling the semiconductor element 1 can be simplified.

When the semiconductor element 1 has been operated at a higher temperature, more heat is transmitted from the semiconductor element 1 to the bonding portion by the bonding material 5 between the metal electrode 2 and the insulating substrate 3. However, since the heat radiation plate 6 has the narrowed portion 40, even when the semiconductor element 1 has been operated at a higher temperature, the degree at which heat generated from the semiconductor element 1 is transferred through the heat radiation plate 6 to the bonding portion by the bonding material 5 between the metal electrode 2 and the insulating substrate 3 can be suppressed.

### J. Tenth Embodiment

In the present embodiment, the semiconductor device according to any one of the above-described first to ninth embodiments is applied to a power conversion device. The application of the semiconductor device according to any one of the first to ninth embodiments is not limited to a specific power conversion device, however a case where the semiconductor device according to any one of the first to ninth embodiments has been applied to a 3-phase inverter will be described below as the tenth embodiment.

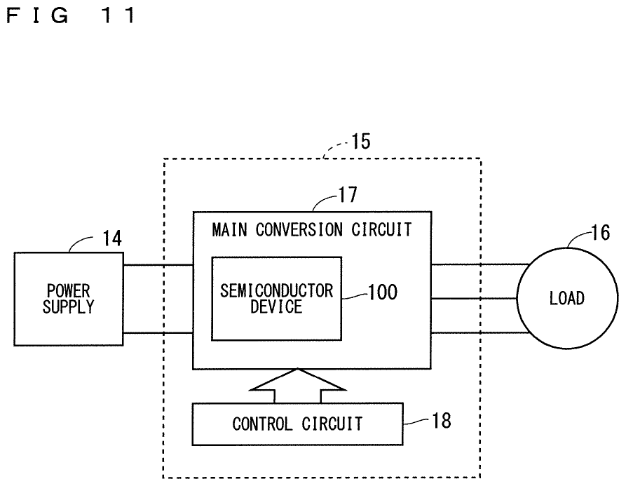

FIG. 11 is a block diagram showing a configuration of a power conversion system to which a power conversion device 15 according to the present embodiment has been applied.

The power conversion system shown in FIG. 11 is composed of a power supply 14, the power conversion device 15, and a load 16. The power supply 14 is a DC power supply that supplies DC power to the power conversion device 15. The power supply 14 can be composed of various components, for example, it can be composed of a DC system, a solar cell, and a storage battery, or it may be composed of a rectifier circuit or an AC/DC converter connected to an AC system. In addition, the power supply 14 may be composed of a DC/DC converter that converts DC power output from the DC system into a predetermined electric power.

The power conversion device 15 is the 3-phase inverter connected between the power supply 14 and the load 16, and it converts the DC power supplied from the power supply 14 into AC power and supplies the AC power to the load 16. As shown in FIG. 11, the power conversion device 15 includes a main conversion circuit 17 that converts DC power into AC power and outputs the AC power, and a control circuit 18 that outputs, to the main conversion circuit 17, a control signal controlling the main conversion circuit 17.

The load 16 is a 3-phase electric motor driven by the AC power supplied from the power conversion device 15. Note that the load 16 is an electric motor mounted on various types of electrical equipment and is not limited to a specific usage application, and it is used, for example, as an electric motor for a hybrid vehicle, an electric vehicle, a railway car, an elevator, or an air conditioner.

The power conversion device 15 will be described in detail below. The main conversion circuit 17 includes a switching element and a free wheeling diode (not shown), and by switching the switching element, the main conversion circuit 17 converts DC power supplied from the power supply 14 into AC power and supplies the AC power to the load 16. While there are various specific circuit configurations of the main conversion circuit 17, the main conversion circuit 17 according to the present embodiment is a 2-level 3-phase full bridge circuit, and it can be composed of six switching elements and six free wheeling diodes arranged anti-parallel to each of the switching elements. A semiconductor device 100, which is the semiconductor device according to any one of the first to ninth embodiments described above, is applied to at least one of each switching element and each free wheeling diode of the main conversion circuit 17. Six switching elements are connected to each two switching elements in series to constitute upper and lower arms, and each of the upper and lower arms constitute each phase (U phase, V phase, and W phase) of the full bridge circuit. Also, output terminals of each of the upper and lower arms, that is, the three output terminals of the main conversion circuit 17, are connected to the load 16.

In addition, the main conversion circuit 17 includes a drive circuit (not shown) that drives each switching element. When the semiconductor device 100 is applied to the switching element, the main conversion circuit 17 may have a configuration in which the semiconductor device 100 has the drive circuit integrated inside, or it may have a configuration in which the main conversion circuit 17 includes the drive circuit separately from the semiconductor device 100. The drive circuit generates a drive signal for driving the switching elements of the main conversion circuit 17 and supplies the drive signal to control electrodes of the switching elements of the main conversion circuit 17. Specifically, a drive signal for turning the switching elements to an on state and a drive signal for turning the switching elements to an off state are output to the control electrodes of each switching element in accordance with a control signal from the later-described control circuit 18. When the switching elements are kept in the on state, the drive signal is a voltage signal (on signal) equal to or higher than a threshold voltage of the switching elements, and when the switching elements are kept in the off state, the drive signal is a voltage signal (off signal) equal to or lower than the threshold voltage of the switching elements.

The control circuit 18 controls the switching elements of the main conversion circuit 17 such that the desired electric power is supplied to the load 16. Specifically, a time during which each switching element of the main conversion circuit 17 should be in the on state (on time) is calculated based on the electric power to be supplied to the load 16. For example, the main conversion circuit 17 can be controlled by a PWM control that modulates the on time of the switching elements in accordance with the voltage to be output. Also, a control command (control signal) is output to the drive circuit provided in the main conversion circuit 17 such that an on signal is output to the switching elements that should be in the on state and an off signal is output to the switching elements that should be in the off state at each point in time. The drive circuit outputs an on signal or an off signal as a drive signal to the control electrodes of each switching element in accordance with the control signal.

In the power conversion device according to the present embodiment, since the semiconductor device according to any one of the first to ninth embodiments is applied to at least any one of the switching elements and the free wheeling diodes of the main conversion circuit 17, reliability can be improved.

In the present embodiment, an example in which the semiconductor device according to any one of the first to ninth embodiments is applied to a 2-level 3-phase inverter has been described, however the application of the semiconductor device according to any one of the first to ninth embodiments is not limited hereto, and the semiconductor device can be applied to various power conversion devices. While a 2-level power conversion device is used in the present embodiment, a 3-level or multi-level power conversion device may also be used, and when electric power is supplied to a single-phase load, the semiconductor device according to any one of the first to ninth embodiments may be applied to a single-phase inverter. In addition, when electric power is supplied to a DC load or the like, the semiconductor device according to any one of the first to ninth embodiments can be applied to a DC/DC converter or an AC/DC converter.

In addition, the power conversion device to which the semiconductor device according to any one of the first to ninth embodiments is applied is not limited to the above-described case where the load is an electric motor, and the power conversion device can be used as, for example, a power supply device of an electrical discharge machine, a laser machine, an induction stove, or a non-contact power supply system, and it can further be used as a power conditioner of a photovoltaic power generation system, a power storage system, or the like.

### K. Eleventh Embodiment

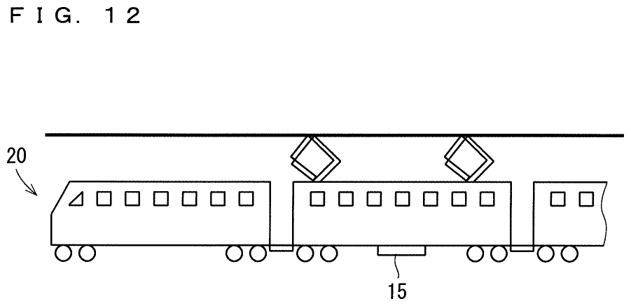

FIG. 12 shows a mobile body 20 of the present embodiment. The mobile body 20 includes the power conversion device 15 according to the tenth embodiment. The mobile body 20 converts DC power input from outside into AC power by the power conversion device 15 and operates using the AC power. The mobile body 20 moves by a motor operated by the AC power output from the power conversion device 15.

By providing the mobile body 20 with the power conversion device 15 according to the tenth embodiment as the power conversion device, reliability can be improved.

While a case where the mobile body 20 is a railway car is assumed in FIG. 12, the mobile body 20 is not limited to a railway car and may be, for example, a hybrid vehicle, an electric vehicle, an elevator, or the like.

Note that each of the embodiments can be freely combined and each of the embodiments can be modified or omitted as necessary.

### EXPLANATION OF REFERENCE SIGNS

1: semiconductor element
2: metal electrode
3, 3a, 3b: insulating substrate
4: metal patterns
5: bonding material
6: heat radiation plate
7: wire
8: case housing
9: sealing material
10, 10b, 10c: hole
11: internal cavity
12a, 12b, 13, 13b, 13c, 13d: depression portion
15: power conversion device
20: mobile body
30, 30a, 30b: insulating layer
40: narrowed portion
70, 71, 72, 73, 74, 75, 76, 77, 78, 79, 100: semiconductor device

1. A semiconductor device comprising:
a heat radiation plate;
at least one insulating substrate;
a semiconductor element; and
a metal electrode,
wherein the at least one insulating substrate is bonded on one main surface of the heat radiation plate,
the semiconductor element is bonded on the one main surface of the heat radiation plate via any of the at least one insulating substrate,
the metal electrode is bonded on the one main surface of the heat radiation plate via any of the at least one insulating substrate, and
the heat radiation plate has, in a region between a region where the semiconductor element is bonded and a region where the metal electrode is bonded, a narrowed portion having a narrower width in a thickness direction than widths of other locations.

2. The semiconductor device according to claim 1, wherein
the heat radiation plate is provided with at least one internal cavity, or at least one through hole or at least one blind hole having an opening in a side surface of the heat radiation plate, and
the narrowed portion has a narrower width in the thickness direction than the widths of other locations due to the at least one internal cavity, the at least one through hole, or the at least one blind hole.

3. The semiconductor device according to claim 2, wherein
any of the at least one internal cavity, the at least one through hole, or the at least one blind hole extends in a direction that intersects with a direction connecting a region where the semiconductor element is bonded and a region where the metal electrode is bonded.

4. The semiconductor device according to claim 2, wherein
the heat radiation plate is formed by combining a plurality of independent portions, and
any of the at least one internal cavity, the at least one through hole, or the at least one blind hole is formed by bringing together depression portions on side surfaces of two or more of the plurality of independent portions.

5. The semiconductor device according to claim 2, wherein
the heat radiation plate is provided with a plurality of internal cavities, a plurality of through holes, or a plurality of blind holes as the at least one internal cavity, the at least one through hole, or the at least one blind hole.

6. The semiconductor device according to claim 2, wherein
any of the at least one internal cavity, the at least one through hole, or the at least one blind hole is an internal cavity, a through hole, or a blind hole having a columnar shape, quadrangular prism shape, or triangular prism shape.

7. The semiconductor device according to claim 1, wherein
at least one depression portion is provided on the one main surface of the heat radiation plate, and
the width of the narrowed portion in the thickness direction is narrowed by the at least one depression portion.

8. The semiconductor device according to claim 7, wherein
the heat radiation plate is provided with a plurality of depression portions as the at least one depression portion.

9. The semiconductor device according to claim 7, wherein
any of the at least one depression portion extends in a direction that intersects with a direction connecting a region where the semiconductor element is bonded and a region where the metal electrode is bonded.

10. The semiconductor device according to claim 7, wherein
any of the at least one depression portion has a rectangular, V-shaped, or semicircular cross section.

11. The semiconductor device according to claim 1, wherein
at least one depression portion is provided on a main surface on a side opposite to the one main surface of the heat radiation plate, and
the width of the narrowed portion in the thickness direction is narrowed by the at least one depression portion.

12. The semiconductor device according to claim 11, wherein
the heat radiation plate is provided with a plurality of depression portions as the at least one depression portion.

13. The semiconductor device according to claim 11, wherein
any of the at least one depression portion extends in a direction that intersects with a direction connecting a region where the semiconductor element is bonded and a region where the metal electrode is bonded.

14. The semiconductor device according to claim 11, wherein
any of the at least one depression portion has a rectangular, V-shaped, or semicircular cross section.

15. The semiconductor device according to claim 7, wherein
the semiconductor element is bonded on the one main surface of the heat radiation plate via a first insulating substrate, which is any one of the at least one insulating substrate,
the metal electrode is bonded on the one main surface of the heat radiation plate via the first insulating substrate,
the first insulating substrate is bonded to the heat radiation plate by solder at a position facing to at least any one of the at least one depression portion, and
solder is contained inside the depression portion facing to the first insulating substrate.

16. The semiconductor device according to claim 1, wherein
the semiconductor element is bonded on the one main surface of the heat radiation plate via a second insulating substrate, which is any one of the at least one insulating substrate, and
the metal electrode is bonded on the one main surface of the heat radiation plate via a third insulating substrate, which is any one of the at least one insulating substrate and is different from the second insulating substrate.

17. The semiconductor device according to claim 1, wherein
the heat radiation plate includes copper, aluminum, or both.

18. The semiconductor device according to claim 1, wherein
the semiconductor element includes a wide band gap semiconductor.

19. The semiconductor device according to claim 18, wherein
the wide band gap semiconductor is silicon carbide, a gallium nitride-based material, or diamond.

20. A power conversion device, comprising:
a main conversion circuit that has the semiconductor device according to claim 1, and which converts input electric power and outputs converted electric power; and
a control circuit that outputs, to the main conversion circuit, a control signal controlling the main conversion circuit.

21. A mobile body, comprising:
the power conversion device according to claim 20; and
an electric motor driven by the electric power output by the power conversion device.
